(19) United States
(12) Patent Application Publication
(10) Pub. No.: US 2025/0176438 A1
(43) Pub. Date: May 29, 2025

(54) SELF-ALIGNED ENCAPSULATION HARD MASK TO SEPARATE PHYSICALLY UNDER-ETCHED MTJ CELLS TO REDUCE CONDUCTIVE RE-DEPOSITION

(71) Applicant: Taiwan Semiconductor Manufacturing Company, Ltd., Hsinchu (TW)

(72) Inventors: Yi Yang, Fremont, CA (US); Dongna Shen, San Jose, CA (US); Vignesh Sundar, Fremont, CA (US); Yu-Jen Wang, San Jose, CA (US)

(21) Appl. No.: 19/029,705

(22) Filed: Jan. 17, 2025

Related U.S. Application Data
(63) Continuation of application No. 18/232,027, filed on Aug. 9, 2023, now Pat. No. 12,245,516.
Application No. 18/232,027 is a continuation of application No. 17/816,035, filed on Jul. 29, 2022, now Pat. No. 11,818,961.
Application No. 17/816,035 is a continuation of application No. 17/121,457, filed on Dec. 14, 2020, now Pat. No. 11,444,241.
Application No. 17/121,457 is a continuation of application No. 16/113,079, filed on Aug. 27, 2018, now Pat. No. 10,868,237.

(51) Int. Cl. H10N 50/01; G11C 11/16; H01F 10/32; H01F 41/34; H10B 61/00; H10N 50/80

(52) U.S. Cl. CPC H10N 50/01; H01F 10/3254; H01F 41/34; H10N 50/80; G11C 11/161; H10B 61/00

(57) ABSTRACT

A method for etching a magnetic tunneling junction (MTJ) structure is described. A MTJ stack is deposited on a bottom electrode wherein the MTJ stack comprises at least a pinned layer, a barrier layer on the pinned layer, and a free layer on the barrier layer, A top electrode layer is deposited on the MTJ stack. A hard mask is deposited on the top electrode layer. The top electrode layer and hard mask are etched. Thereafter, the MTJ stack not covered by the hard mask is etched, stopping at or within the pinned layer. Thereafter, an encapsulation layer is deposited over the partially etched MTJ stack and etched away on horizontal surfaces leaving a self-aligned hard mask on sidewalls of the partially etched MTJ stack. Finally, the remaining MTJ stack not covered by hard mask and self-aligned hard mask is etched to complete the MTJ structure.

### PRIORITY DATA

The present application is a continuation application of U.S. application Ser. No. 18/232,027, filed Aug. 9, 2023, which is a continuation application of U.S. application Ser. No. 17/816,035, filed Jul. 29, 2022 and issued as U.S. Pat. No. 11,818,961, which is a continuation application of U.S. application Ser. No. 17/121,457, filed Dec. 14, 2020 and issued as U.S. Pat. No. 11,444,241, which is a continuation application of U.S. application Ser. No. 16/113,079, filed Aug. 27, 2018 and issued as U.S. Pat. No. 10,868,237, each of which is herein incorporated by reference in its entirety.

### TECHNICAL FIELD

This application relates to the general field of magnetic tunneling junctions (MTJ) and, more particularly, to etching methods for forming MTJ structures.

### BACKGROUND

Fabrication of magnetoresistive random-access memory (MRAM) devices normally involves a sequence of processing steps during which many layers of metals and dielectrics are deposited and then patterned to form a magnetoresistive stack as well as electrodes for electrical connections. To define the magnetic tunnel junctions (MTJ) in each MRAM device, precise patterning steps including photolithography and reactive ion etching (RIE), ion beam etching (IBE) or their combination are usually involved. During RIE, high energy ions remove materials vertically in those areas not masked by photoresist, separating one MTJ cell from another.

However, the high energy ions can also react with the non-removed materials, oxygen, moisture and other chemicals laterally, causing sidewall damage and lowering device performance. To solve this issue, pure physical etching techniques such as Ar RIE or ion beam etching (IBE) have been applied to etch the MTJ stack. However, due to the non-volatile nature, physically etched conductive materials in the MTJ and bottom electrode can form a continuous path across the tunnel barrier, resulting in shorted devices. A new approach to overcome this dilemma is thus needed if one wants to unleash the full potential of this physical etch to pattern the future sub 60 nm MRAM products.

Several references teach multi-step etching methods to form MTJ's, including U.S. Pat. No. 9,793,126 (Dhindsa et al), U.S. Pat. No. 9,722,174 (Nagel et al), and U.S. Pat. No. 8,883,520 (Satoh et al). All of these references are different from the present disclosure.

### SUMMARY

It is an object of the present disclosure to provide an improved method of forming MTJ structures.

Yet another object of the present disclosure is to provide a method of forming MTJ devices using a physical underetch to avoid both chemical damage and physical shorts.

A further object of the present disclosure is to provide a method of forming MTJ devices using a physical underetch to avoid both chemical damage and physical shorts where separate and non-interacting MTJ cells are made using encapsulation material as a self-aligned process.

In accordance with the objectives of the present disclosure, a method for etching a magnetic tunneling junction (MTJ) structure is achieved. A MTJ stack is deposited on a bottom electrode wherein the MTJ stack comprises at least a pinned layer, a barrier layer on the pinned layer, and a free layer on the barrier layer. A top electrode layer is deposited on the MTJ stack. A hard mask is deposited on the top electrode layer. The top electrode layer and hard mask are etched. Thereafter, the MTJ stack not covered by the hard mask is etched, stopping at or within the pinned or the seed layer. Thereafter, an encapsulation layer is deposited over the partially etched MTJ stack and etched away on horizontal surfaces leaving a self-aligned hard mask on sidewalls of the partially etched MTJ stack. Finally, the remaining MTJ stack not covered by hard mask and self-aligned hard mask is etched to complete the MTJ structure.

### BRIEF DESCRIPTION OF THE DRAWINGS

In the accompanying drawings forming a material part of this description, there is shown:

FIGS. 1 through 6 illustrate in cross-sectional representation steps in a preferred embodiment of the present disclosure.

### DETAILED DESCRIPTION

In a typical process, the whole MTJ stack is patterned by a single step of etch, either by chemical RIE or physical Ar RIE or IBE. It therefore creates either chemical damage or physical shorts on the MTJ sidewall. In the process of the present disclosure, we first partially etch the MTJ stack to minimize the physical re-deposition. Then, using encapsulation material as a self-aligned hard mask, the remaining MTJ is etched. This new process avoids chemical damage and physical shorts simultaneously. Moreover, the second step of etch is a self-aligned process, meaning it does not require a complicated photolithography step, where the overlay is hard to control, especially for sub 60 nm MRAM devices.

In the process of the present disclosure, the MTJ stack is first partially etched by a physical etch such as RIE or IBE using different gas plasma such as Ar and Xe, so that there is no chemical damage but only conductive re-deposition on the sidewall. The amount of re-deposition is dependent on the etch amount. By intentionally under etching, e.g., only etching away the free layer, tunnel barrier and/or part of the pinned or the seed layer, the re-deposition on the tunnel barrier sidewall can be significantly reduced or totally removed. An encapsulation material is deposited to protect the earlier etched MTJ. A RIE or IBE etch partially clears out the portion of encapsulation material that is on top and bottom of the MTJ patterns. Next, using the encapsulation material left on the MTJ sidewalls as a self-aligned hard mask, the remaining MTJ is etched, creating separate and non-interacting MTJ cells. Regardless of what type of etch is used, the free layer and tunnel barrier layer would not be affected by this step due to the encapsulation material's protection, thus preserving high device performance.

Referring now to FIGS. 1 through 6, the novel method of the present disclosure will be described in detail. Referring now more particularly to FIG. 1, there is shown a bottom electrode 10 formed on a substrate, not shown. Now, layers are deposited on the bottom electrode to form a magnetic tunnel junction. For example, seed layer 12, pinned layer 14, tunnel barrier layer 16, and free layer 18 are deposited.

There may be one or more pinned, barrier, and/or free layers. A metal hard mask 20, such as Ta, TaN, Ti, TiN, W, Cu, Mg, Ru, Cr, Co, Fe, Ni or their alloys, is deposited to a thickness of 10-100 nm, and preferably ≥50 nm, on top of the MTJ stack. This hard mask will be used as a top electrode. Finally, a dielectric hard mask material 22, such as SiO₂, SiN, SiON, SiC or SiCN, is deposited to a thickness of ≥20 nm onto the top electrode 20. Photoresist is patterned by 248 nm photolithography, for example, to form photoresist pillar patterns 24 with size d1 of ˜70-80 nm and height ≥200 nm.

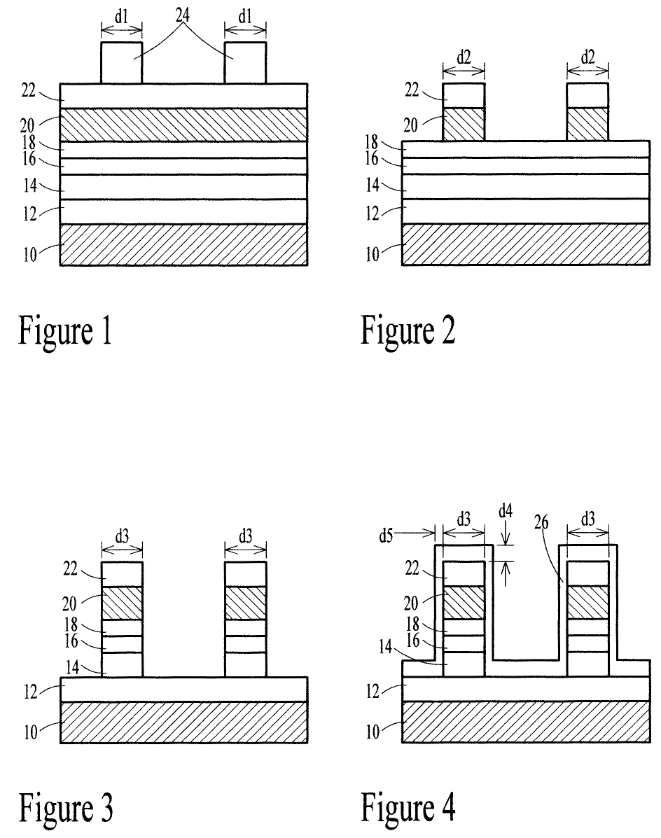

Now, as illustrated in FIG. 2, the dielectric and metal hard masks 22 and 20 are etched by a fluorine carbon based plasma such as CF₄ or CHF₃ alone, or mixed with Ar and N₂. O₂ can be added to reduce the pillar size d2 from 50-60 nm to 30-40 nm. They can also be etched by physical RIE or IBE (pure Ar), followed by large angle (70-90° with respect to the pillar's normal line) IBE trimming, forming pillar size d2 of 30-40 nm.

Referring now to FIG. 3, the MTJ stack is partially etched using physical RIE (pure Ar or Xe) or IBE stopping either on the pinned layer or the seed layer with similar pattern size, to minimize the metal re-deposition on the tunnel barrier. Because of the nature of a physical etch, there is no chemical damage. The height h of the partially etched MTJ stack is between about 5 and 30 nm.

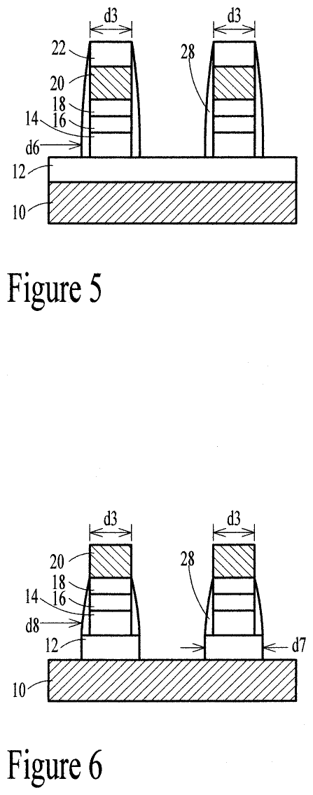

Now, as illustrated in FIG. 4, an encapsulation material 26 made of dielectric materials such as SiN, SiC, SiCN, carbon, or TaC or metal oxides such as Al₂O₃ or MgO with thickness d4 of 5-30 nm, is either in-situ or ex-situ deposited by CVD, PVD or ALD onto the partially etched MTJ patterns. The portion of the encapsulation material on top and bottom of the patterns is etched away by RIE or IBE, leaving encapsulation spacers 28 on the sidewalls, as shown in FIG. 5, having a thickness d6 of 10-30 nm. Depending on the material used for the spacer, different plasma can be used for this etching step. For example, a fluorine carbon based plasma such as CF₄ or CHF₃ can be used for SiN, SiC, and SiCN, O₂ can be applied for carbon, a fluorine carbon such as CF₄ or CHF₃ or a halogen such as Cl₂, or their combination, can be used for TaC, and a halogen such as Cl₂ alone or mixed with Ar can be used for Al₂O₃ and MgO.

Finally using the encapsulation 28 left on the sidewalls of the MTJ patterns as a self-aligned hard mask, as shown in FIG. 6, the remaining MTJ stack such as the pinned layer 14 and/or seed layer 12 can be etched by RIE or IBE. When a RIE etch is used, since the pinned layer and seed layer fabricated by this method are larger than the free layer, the chemical damage on the pinned layer and seed layer would not affect its central portion which is aligned with the free layer. When physical RIE or IBE is used, the metal re-deposition from the pinned and seed layers would not be in contact with the tunnel barrier due to the encapsulation's protection. Note that this pinned and seed layer etch is a self-aligned step, meaning it has no overlay control issue, which is usually associated with sub 60 nm MRAM device fabrication.

More importantly, the pinned and seed layers' sizes are greatly dependent on the thickness of the encapsulation sidewall serving as the hard mask, which is determined by its initial deposition thickness and later etch conditions. By tuning these parameters, one can precisely control the pinned and seed layers' sizes according to the device design. For instance, one can create a thick spacer having a thickness d8 of 10-20 nm on the free layer's sidewall so that the later defined tunnel barrier and pinned layers are of the size d7 of 50-60 nm, larger than the free layer d3 of 40-50 nm. This is particularly critical for small cell size devices since it allows for strong pinning strength, increasing the energy barrier and reducing the switching current.

In summary, the process of the present disclosure uses a physical under etch to avoid both chemical damage and physical shorts. Moreover, separate and non-interacting MTJ cells are made using encapsulation material as a self-aligned process, meaning it has no overlay control issue, which is usually associated with sub 60 nm MRAM device fabrication. It is thus possible to replace the widely used chemical RIE etch, which inevitably brings chemical damage on the MTJ sidewall. This process will be used for MRAM chips of the size smaller than 60 nm as problems associated with chemically damaged sidewalls and re-deposition from the MTJ stack and bottom electrode become very severe for the smaller sized MRAM chips.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A method, comprising:
forming a bottom electrode over a substrate;
depositing a seed layer over the bottom electrode;
depositing a pinned layer over the seed layer;
depositing a tunnel barrier layer over the pinned layer;
depositing a free layer over the tunnel barrier layer;
patterning the pinned layer, the tunnel barrier layer, and the free layer to form a magnetic tunneling junction (MTJ) stack to expose the seed layer;
depositing an encapsulation layer over the MTJ stack and a top surface of the seed layer;
etching the encapsulation layer to form a spacer extending alone sidewalls of the MTJ stack; and
after the etching of the encapsulation layer, etching the seed layer using the spacer as an etch mask.

2. The method of claim 1, further comprising:
depositing a metal hard mask over the free layer; and
depositing a dielectric hard mask over the metal hard mask.

3. The method of claim 2, wherein the metal hard mask comprises Ta, TaN, Ti, TiN, W, Cu, Mg, Ru, Cr, Co, Fe, Ni, or an alloy thereof.

4. The method of claim 2, wherein the dielectric hard mask comprises SiO₂, SiN, SiON, SiC or SiCN.

5. The method of claim 2, wherein a thickness of the metal hard mask is greater than or equal to 50 nm.

6. The method of claim 2, wherein a thickness of the dielectric hard mask is greater than or equal to 20 nm.

7. The method of claim 2, wherein the etching of the seed layer removes the dielectric hard mask over the metal hard mask.

8. The method of claim 1, wherein the encapsulation layer comprises SiN, SiC, SiCN, carbon, TaC, Al₂O₃, or MgO.

9. The method of claim 1, wherein the etching of the seed layer exposes the bottom electrode.

10. A method, comprising:
forming a bottom electrode over a substrate;
depositing a seed layer over the bottom electrode;
depositing a pinned layer over the seed layer;
depositing a tunnel barrier layer over the pinned layer;
depositing a free layer over the tunnel barrier layer;
depositing a metal hard mask over the free layer;
depositing a dielectric hard mask over the metal hard mask;
patterning the pinned layer, the tunnel barrier layer, the free layer, the metal hard mask, and the dielectric hard mask to form a magnetic tunneling junction (MTJ) stack to expose the seed layer;
depositing an encapsulation layer over the MTJ stack and a top surface of the seed layer;
etching the encapsulation layer to form a spacer extending alone sidewalls of the MTJ stack; and
after the etching of the encapsulation layer, etching the seed layer using the spacer as an etch mask.

11. The method of claim 10,
wherein the etching of the encapsulation layer exposes the dielectric hard mask,
wherein the etching of the seed layer removes the exposed dielectric hard mask.

12. The method of claim 10, wherein the etching of the seed layer exposes the bottom electrode.

13. The method of claim 10,
wherein the encapsulation layer comprises SiN, SiC, or SiCN,
wherein the etching of the encapsulation layer comprises use of a fluorine carbon based plasma.

14. The method of claim 10,
wherein the encapsulation layer comprises carbon,
wherein the etching of the encapsulation layer comprises use of oxygen.

15. The method of claim 10,
wherein the encapsulation layer comprises TaC,
wherein the etching of the encapsulation layer comprises use of CF₄, CHF₃ or Cl₂.

16. The method of claim 10,
wherein the encapsulation layer comprises Al₂O₃ or MgO,
wherein the etching of the encapsulation layer comprises use of Cl₂, argon, or a combination thereof.

17. A device, comprising:
a bottom electrode;
a magnetic tunneling junction (MTJ) stack over the bottom electrode and comprising:
a seed layer interfacing the bottom electrode,
a pinned layer over the seed layer,
a tunnel barrier layer over the pinned layer, and
a free layer over the tunnel barrier layer;
an encapsulation spacer extending along sidewalls of the MTJ stack; and
a top electrode over the MTJ stack,
wherein the encapsulation spacer is disposed on a top surface of the seed layer.

18. The device of claim 17, wherein the encapsulation spacer comprises SiN, SiC, SiCN, carbon, TaC, Al₂O₃, or MgO.

19. The device of claim 17, wherein sidewalls of the top electrode are not covered by the encapsulation spacer.

20. The device of claim 17, wherein the encapsulation spacer interfaces sidewalls of the pinned layer, the tunnel barrier layer, and the free layer.
